(19) United States
(12) Patent Application Publication
(10) Pub. No.: US 2023/0257888 A1
(43) Pub. Date: Aug. 17, 2023

(54) Method and Apparatus of Electric Current Measurement in Electrolyser Stack and Electrolyser

(71) Applicant: Green Hydrogen Systems A/S, Kolding (DK)

(72) Inventors: Christian Buhl Sørensen, Kolding (DK); Henrik Gøbel Füchtbauer, Odder (DK); Vickie Schultz-Falk, Harndrup (DK); Anders Rønne Rasmussen, Svendborg (DK)

(21) Appl. No.: 18/110,440

(22) Filed: Feb. 16, 2023

Related U.S. Application Data
(60) Provisional application No. 63/311,077, filed on Feb. 17, 2022.

(51) Int. Cl. C25B 1/04; G01R 19/00; C25B 15/033

(52) U.S. Cl. CPC C25B 1/04; G01R 19/0092; C25B 15/033

(57) ABSTRACT

A method of electric current measurement at an electrolyser cell comprises the following steps: provide at least one sensor having an element which is responsive to the presence of a magnetic flux and/or magnetic flux changes adjacent to an input or exit manifold channel outside of a current injector plate in the electrolyser stack, ensure an electric or a wireless connection between the sensor and a recording and/or display device, supply an electrical potential difference between two current injector plates having the electrolyser cell stack arranged between them, capture a signal value indicative of magnetic flux and/or magnetic flux change at the sensor location by at least one sensor, make at least one signal value available for storage and/or transmission to a remote location through the wired and/or wireless connection. An electrolyser comprising a stack of cells where the electrolyser accommodates a sensor is also provided.

### RELATED APPLICATIONS

This application claims priority to U.S. Provisional Application No. 63/311,077, filed Feb. 17, 2022, the disclosure of which is incorporated herein by reference in its entirety.

### INTRODUCTION

In electrolysers of the stacked cell type where an alkaline water mixture is supplied to a range of individual cells through a manifold channel for the purpose of obtaining electrolysed hydrogen and oxygen, there is bound to be an electrical potential difference between the two cells or half cells residing next to the current injector plates arranged at each end of a range of individual cells. This electrical potential difference will inevitably lead to the generation of electric currents in the electrolyte fluid in the manifolds due to the alkaline nature of the electrolyte and followingly low ohmic resistance in the fluid. It is of interest to know the size of the electrical current running in the channels, and direct galvanic measurements are not practical due to the high potential differences, the corrosive nature of the alkaline fluid, and the pressure difference between the surroundings and the vessels inside the stack. An alternative to direct galvanic measurements of electric currents running in the electrolyte manifold channels is thus desired.

The invention comprises a method of electric current measurement at an electrolyser stack comprising the following steps: provide at least one sensor comprising an element which is responsive to the presence of a magnetic flux and/or magnetic flux changes adjacent to an electrolyte manifold channel outside of a current injector plate in the electrolyser stack, ensure an electric or a wireless connection between the sensor and a recording and/or display device, supply an electrical potential difference between two current injector plates having the cell stack arranged between them, capture at least one signal value indicative of magnetic flux and/or magnetic flux change at the sensor location by the at least one sensor, make the at least one signal value available for storage and/or transmission to a remote location through the wired and/or wireless connection.

The electrolyte in the manifold channels may carry a significant current when the stack is energized by electric current passing from one electric current injector plate to an opposed electric current injector plate through the range of individual electrolyser cells residing between the two electric current injector plates. The current in the manifold channel may be measured at a location just outside of the cell stack at the far side of the current injector plate, through which the electrolyte and gas manifold channels are passed. The current measured at this location passes in or out of the stack and may thus be indicative of an undesirable condition within the stack, and it is important that it is registered. The end plate is usually made from iron and may, more or less directly, be coupled to a zero electrical potential such as earth. In any event, the various channels passing through the end plate are not necessarily electrically insulated therefrom. Currents may thus pass in the end plate, and these currents are difficult to measure. The presence of a sensor responsive to magnetic field and/or magnetic field changes close to the manifold channels outside of the current injector plates in the stack, will make it possible to sense the magnetic field caused by electric currents in the electrolyte, and thus an indication of the current flux and/or current flux changes in the electrolyte passing in the manifold channel may be obtained. The current in the channel may be observed between the first cell fluid connection and first short circuit between channel fluid and the end plate. If the channel remains electrically isolated from the end plate, the current in the channel may be observed even outside of the end plate by the use of a sensor as described. The obtained current indication is transmitted from the site of the sensor to a remote location to be recorded and/or displayed. Thereby, the current indicative signal becomes available for a control unit for the plant and automatic changes may be instigated in response to detected current levels or current level changes.

In an embodiment, an insulation plate is generated with a pocket, and arranged adjacent to a backside of a current injector, whereby the pocket is arranged to surround at least one of the following: an electrolyte manifold channel, an oxygen manifold channel, or a hydrogen manifold channel, in a predetermined distance therefrom leaving a material rim around the respective channel, and whereby the at least one sensor is inserted into the pocket.

The insulator plate is there to ensure that the electrical potential of the current injector, which is connected to a supply of DC electricity during electrolysation, does not also reside with the end plate. In pressurized stacks, the end plates are urged towards each other in order to offset the internal pressure in the stack and contain the various products therein. Thus, the insulation plate will be subject to the pressurization forces and must be sufficiently strong to sustain the pressure forces between the end plate and the current injector plate. Thus, tampering with this insulation plate and embedding sensitive electronic equipment in it, requires careful consideration of both mechanical and electrical complicated issues.

In an embodiment, the pocket is arranged adjacent to the current injector plate, such that the insulation plate is complete and unbroken against the end plate. The pocket may in this case extend into the current injection plate in a recess provided to this end adjacent to the insulation plate. Here the sensor may be placed around the channel to be observed, in which case the overall thickness of the insulation plate does not need to be changed.

In another embodiment, the pocket is provided adjacent to the end plate, and thus the insulator plate is unbroken and complete at the face abutting the current injector plate. In this embodiment, the pocket may extend into a recess adjacent to the insulation plate and created in the end plate around the channel to be observed, in which case the overall thickness of the insulation plate does not need to be changed.

In an embodiment, signals indicative of currents or current changes in all of the following: a catholyte manifold channel, an anolyte manifold channel, a hydrogen manifold channel, and an oxygen manifold channel of a stack, are captured and made available for storage and/or transmission.

It is preferred that the currents passing in both the electrolyte manifold channels as well as in both of the hydrogen and oxygen manifold channels are monitored. This allows for a more sensitive and precise measurement. Also, in some types of electrolysers, the anolyte and the catholyte have separate flow circuits and in order to capture a current running between the anolyte and catholyte and not contributing to the electrolysis process, electrical current levels in each of the manifold channels must be observed. Electric current densities are also captured at the manifold channels leading produced gases away from the electrolyser stack as in alkaline water electrolysers these manifold channels carry a mixture of anolyte and oxygen and a mixture of catholyte and hydrogen respectively, and due to the presence of the electrolyte in these two channels, an electric current density shall also be present within the channel. These current magnitudes may also provide important information regarding the present state within the stack during electrolysation, and a feedback mechanism will be realizable based on such data. Hereby a more optimized operation of a multitude of stacks may be obtained as such entities as electrical current feed and electrolyte flows in individual stacks may be regulated.

In an embodiment, an O-ring or similar gasketing device is pressured towards the material of the material rim around each of the manifold channels whereby the O-ring is adapted to reside in a u-shaped furrow in the current injector plate or in a u-shaped furrow in the end plate and/or in a U-shaped furrow in the insulation plate.

The O-rings aid to uphold the pressure inside of the electrolyte manifold channels in pressurized electrolysers. This pressure may be 40 bar or higher. It is thus required, that the material rim around the electrolyte manifolds is sufficiently strong to withstand the pressure in the radial direction from within the channel. And thus, the material rim needs to have some thickness, and a gasketing is needed against the neighbouring element, whether it be the electric current injector plate or the end plate. This gasketing is assured by the O-ring. The ring is made from a suitably flexible material and is preferably inserted, at least partially, in a furrow in the current injector plate/end plate to ensure its position. Alternatively, or additionally, the gasket is positioned in a furrow in the insulator plate.

In an embodiment of the method, a sensor is arranged with a core material having high magnetic permeability and is subject to the magnetic field generated by the electric current in the manifold channel and further at least one of a hall element, and a coil is provided adjacent to the core material, and an electric response signal originating from the hall element and/or the coil is made available for storage and/or transmission to a remote location.

By having a magnetic core with high magnetic permeability, a coil and a hall sensor, a zero-flux type sensor may be provided, whereby an electric current is fed through the coil, which is wound around the core, in order to off-set the magnetic flux generated by the electric current in the channel. The combined resulting magnetic flux in the core is measured by the hall element, which to this purpose is inserted into a radially shaped slit in the core. A small circuit including an amplifier is used to keep the signal from the hall sensor constant, and the output signal is the potential over the coil/electric current passing through the coil, which must be maintained to get the unchanged signal from the hall sensor. Hereby a more precise sensor with a high sensitivity over a wide range may be provided.

It is an option to provide a coil which is wound around the electrolyte channel and monitor currents and/or potentials provoked in such a coil due to the current changes in the electrolyte channel. Such a coil would be especially well suited to monitor ripples in the electric currents in the electrolyte channel. In theory, by continually integrating the signal from such a coil from the start, it would be possible to obtain credible values for DC electric current levels in the channel.

In an embodiment, the pocket is provided with a depth in the thickness direction of the insulator plate of no more than ⅘ of the insulator plate thickness.

Usually, the insulator plate does not need to be thick as the electric potential difference between an end plate and the current injector plate is small, but in order to accommodate the sensor, the plate needs to have a higher thickness, or it must be made from a material which is stronger and have improved electric insulation properties. However, in any case, a reasonable fraction of the plate thickness needs to remain unscathed by the provision of the pocket, to safeguard both strength and electrical insulation properties in the region of the pocket. Thus, it is recommended that a certain fraction of the thickness is saved for this purpose, such that the pocket depth is no more than ⅘ of the thickness of the insulator plate.

In an embodiment, the pocket is milled out in the insulator plate prior to the insertion of the sensor.

This may be especially advantageous if the insulator plate is initially cut out from endless lanes of material.

The pocket may be open towards the surroundings in the radial direction, preferably in a general direction in which the distance between the manifold channel and a radial surface of the insulator plate is smallest. This embodiment allows for the sensor to be easily exchangeable.

In an embodiment, in a step prior to assembly of the stack, voids around the sensor are filled out with a hardenable resin, such that the insulator plate material in the pocket and sensor and transmission element are embedded in the resin.

This embodiment will on the one hand provide excellent protection of the sensor and transmitter, however on the other hand, it will not allow exchange or dis-assembly of the sensor and the transmitter. Also, with this embodiment the material rim around the manifold channel may be made thinner in the radial direction as pressure forces from the fluid in the channel may be absorbed by the hardened resin and the sensor itself and further dispersed in radial direction away from the channels. “Thin” in this connection means that the material rim will not be strong enough on its own to withstand the radial pressure from the fluids in the channel when pressurized.

In an embodiment, the sensor element is inserted into the pocket prior to, during, or after the assembly of the stack.

By this method, it will be easy to provide a sensor in the stack which may be accessed and removed from the stack or inserted in the stack at will. If the pocket is not open to the surroundings, insertion is only an option prior to or during assembly of a stack, whereas in configurations where the pocket is open, the insertion may take place at any time.

In a further embodiment, the invention comprises an electrolyser having a stack of cells and embedded in the stack, catholyte and anolyte manifolds adapted to feed catholyte and anolyte to respective catholyte and anolyte cell chambers, wherein catholyte chambers further comprise a cathode adapted to release hydrogen, and anolyte chambers comprise an anode adapted to release oxygen, when an electrolyte comprising alkaline water is supplied through the respective electrolyte manifolds and wherein gas and electrolyte manifolds are provided and adapted for the capture of the produced gasses. It is preferred that a pocket is provided around at least on of an electrolyte input manifold channel, an oxygen output manifold channel, a hydrogen output manifold channel and placed at a predetermined distance from the respective channel and disposed in an insulator plate arranged between an end plate and a current injector plate at one end of the stack whereby the pocket is adapted to accommodate a sensor.

A pocket of this nature shall allow a sensor such as a sensor responsive to magnetic fields to reside therein and be sufficiently close to the manifold channels to sense possible electric currents passing in the channel. Other types of sensors, such as microphones, accelerometers and thermo elements may be provided in the pocket, in order for other properties such as sound and/or vibrational levels and temperatures to be monitored. As the insulator residing between the end plates and the current injection plate is subject to high pressure, it is not evident, that a pocket for holding any kind of sensor might well be provided therein. Surprisingly, it has been determined that by slightly increasing the thickness of the insulator plate, it becomes possible to include various kinds of sensors therein.

In an embodiment, the insulator plate is comprised of two plates which are assembled face to face, where one of the plates comprises a cut-out corresponding to the pocket, and where an annular element is provided around the channel surrounded by the pocket. Possibly, the two insulator plates and the annular elements are glued and/or welded to each other such that when pressurized between the end plate and the current injector plates, no fluid shall penetrate their intersection. In such an embodiment, the pocket may be stamped out from a plate element, which would make production fast and easy.

In an embodiment, at least one magnetic flux and/or magnetic flux change responsive touchless sensor is arranged in the pocket whereby the sensor is adapted to register values indicative of electric current densities and/or electric current density changes in a respective manifold channel and whereby further a transmission element for wireless or wired transmission of registered values is provided in the pocket along with the sensor.

Magnetic flux is registerable by an element such as a hall sensor. Further, a coil may be used to register magnetic flux changes. If a coil is provided and has a number of windings around a manifold channel, any changes in the electric current level in the channel will be registerable as an electrical potential. One or the other or both of such elements may be provided in the pocket along with a transmission element such as an amplifier connected to a wire connection or a wireless transmitter.

In a preferred embodiment, the pocket surrounds a manifold electrolyser channel and is at least partially open to the surrounding.

If an opening is provided, it may extend along a radial surface of the insulation plate and allow access to the pocket from the outside. This allows sensors, amplifiers wire connected/wireless transmitters to be inserted or removed from the pocket without taking the electrolyser stack apart.

In a preferred embodiment, the sensor comprises a hall element and at least one of the two: a magnetic material with a high magnetic permeability, a coil.

A core is usually made of magnetic material with a high magnetic permeability and is used to confine and guide magnetic field lines. It is usually made of ferrimagnetic metal such as iron, or ferrimagnetic compounds such as ferrites. The high permeability, relative to the surrounding material causes the magnetic field lines to be concentrated in the core material. With a hall element, the magnetic flux may be measured at the electrolyte channel, however in order to retain an improved signal to noise ratio and a larger measurement window, it is preferred that the hall element is inserted in a core made as described which surrounds the channel leaving only a narrow gap for the hall sensor. With this arrangement, the magnetic flux lines originating from the electric current in the channel shall be much concentrated at the hall element. It is further an advantage if a coil is provided around at least a part of the core, such that an electric current in the coil may off-set the magnetic flux therein originating from the electric current in the channel. A zero-flux sensor may thereby be provided which allows high precision measurements in a wide measurement range.

In an embodiment of the invention, it is preferred that the predefined distance is sufficient for the pressure in the channel to be contained.

In this embodiment, the predefined distance between the channel inner surface and the surfaces of the pocket which are closest to the channel is sufficient for the material of the insulator plate to keep its shape and position when pressure is raised in the channel. Thereby an O-ring or another gasketing device between the insulator plate and an opposed surface shall remain seated in its furrow, and no leaks are likely.

In an embodiment, the sensor circumscribes the respective channel, and the pocket is filled out by the sensor and/or possible hardenable resin provided between the sensor parts and pocket walls.

In this embodiment, either sensor body or a hardened resin shall provide a strengthening means, such that even if the material rim between the pocket and the channel is not in itself strong enough to contain the pressure, the stresses in the rim shall be offset by straining the sensor and/or the resin around the sensor. In this way the predetermined distance outlining the size of the rim may be kept relatively small, such that the pressures inside the channel are transferred through the material rim and the sensor and/or the resin to the surrounding parts of the insulator plate. Any gasketing means, such as an O-ring shall thus remain in place and provide the desired gasketing, even if pressures inside the channel surpass the pressure carrying capacity of the material rim.

Various exemplifying and non-limiting embodiments both as to constructions and to methods of operation, together with additional objects and advantages thereof, will be best understood from the following description of specific exemplifying and non-limiting embodiments when read in conjunction with the accompanying drawings.

In the above embodiments it is taken for granted, that the sensor is not subject to the pressure in the channel. However, it is an option to arrange the sensor inside the pressurized area, seating the O-rings outside of the pocket. Such an arrangement would exclude any larger opening from the pocket to the surroundings, and generally not offer any important advantages.

The verbs “to comprise” and “to include” are used in this document as open limitations that neither exclude nor requires the existence of unrecited features. The features recited in dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF THE FIGURES

FIG. 1 shows a 3D view of a part of the insulation plate with the pocket,

FIG. 2 is a plane view of an insulation plate where pockets have been milled out,

FIG. 3 is a plane view of area D in FIG. 2 in enlarged scale,

FIG. 4 shows a section along lines F-F indicated in FIG. 3,

FIG. 5 is a section through a prior art electrolyser,

FIG. 6 is an enlarged view of a part of the electrolyser shown in FIG. 5,

FIG. 7 shows an enlarged view of the part of the electrolyser shown in FIG. 6,

FIG. 8 shows in schematic form the basic parts of a sensor,

FIG. 9 is the sensor shown in FIG. 8, however with a wireless transmitter,

FIG. 10 shows a schematic representation of the flow volumes inside a cell stack 1 and

FIG. 10A shows the essentials of FIG. 10 in black and white.

### DETAILED DESCRIPTION

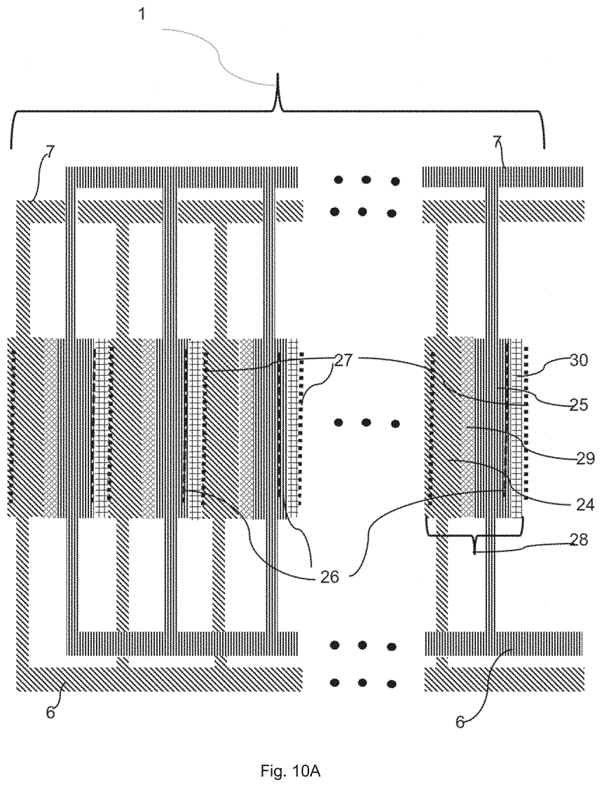

In FIG. 5 a prior art electrolyser 1 is shown in a 3D sectional view, and here a range of cell frames 2 are maintained under axial pressure between two end plates 3. At each end plate 3, a current injector plate 4 is arranged, and the individual cell frames 2 are stacked between the two current injector plates 4. Alternate cell frames are associated with a bipolar plate 30 and a diaphragm 29 respectively as known in the art, and diaphragms 29 and bipolar plates 30 are schematically seen in FIG. 10. Also in this figure, the anolyte chambers 24 and cathode chambers 25 as well as cathode 26 and anode 27 are shown. Also, the extend of a single cell 28 and the entire stack of cell 1 is indicated.

In FIG. 5, a proximal endplate 3 is shown with four axially through going channels: anolyte and catholyte input channels 6 respectively at one side and oxygen and hydrogen exit channel 7 respectively at an opposed side. One of oxygen and hydrogen output channel 7 is shown in an enlarged sectional view in FIG. 6. This enlarged view allows the insulation plate 8 between the endplate 3 and the current injector plate 4 to be seen.

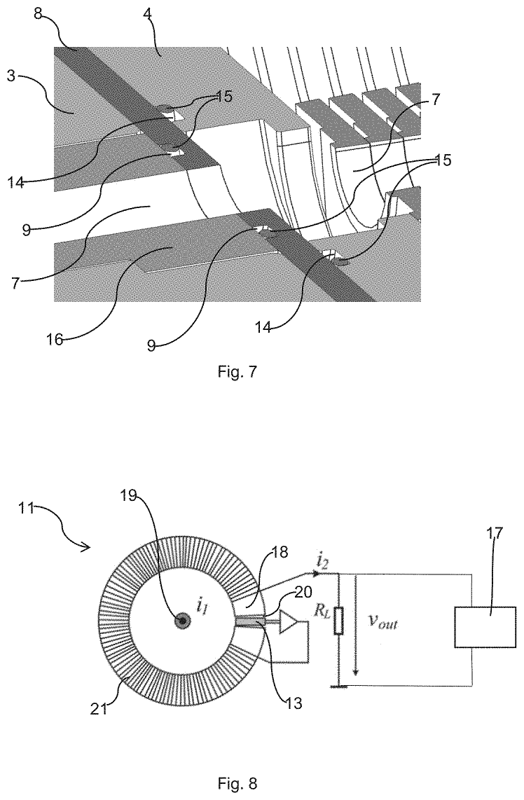

In FIG. 7 an enlarged view of the channel in FIG. 6 is provided and FIG. 7 also illustrates how the channel 7 runs axially through the insulation plate 8. As further seen in this figure, current injector plate O-ring furrow 14 is provided with an O-ring 15. Further, an insulator plate furrow 9 is shown, also with an O-ring 15. The two O-rings 15, one on each side of the insulation plate 8 ensures leak tight connection through the insulation plate 8. A somewhat similar arrangement will be provided for the insulator plate with the pocket 10 according to the invention, with an O-ring furrow 9, where an O-ring may be seated and pressured towards the rim 5 around the channel 6,7.

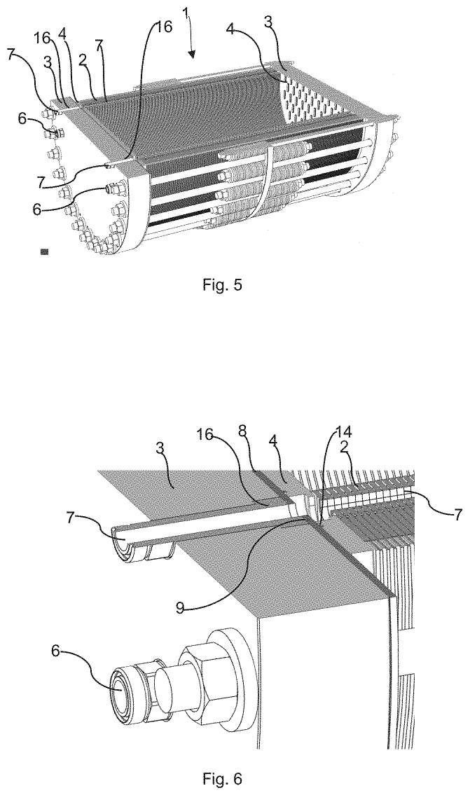

In FIG. 4, an enlarged section of an insulator plate 8 according to an embodiment of the invention is shown. Furrows 9 are provided in the insulation plate 4 and/or in the endplate and/or in the current injector plate.

As further seen in FIGS. 6 and 7, a channel bushing 16 is inserted through the end plate, and the O-ring in the insulation plate furrow 9 contacts an end-part of the channel bushing 16.

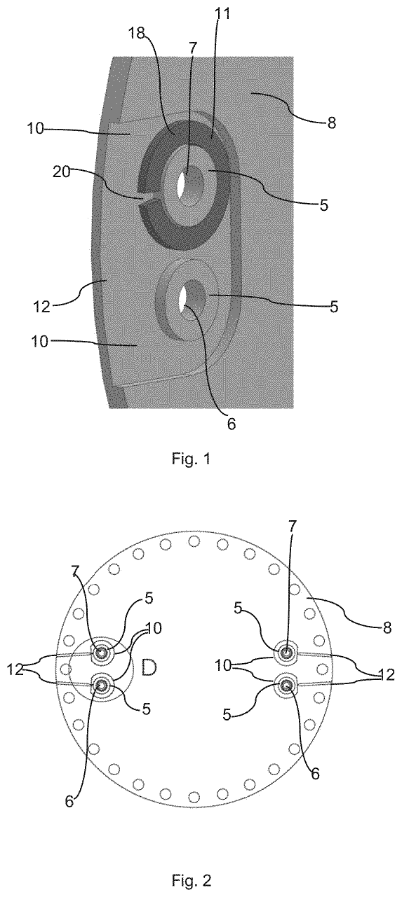

In the 3D view of a part of an insulation plate 8 according to an embodiment of the invention in FIG. 1, a pocket 10 is seen as well as the channels 7,6 and around each channel 6,7 a material rim 5 of the insulator plate 8 is left with the original insulator plate thickness. This material rim 5 may comprise a furrow 9 as best seen in FIG. 4. An O-ring (not shown in FIG. 4) may be mounted in the furrow 9. The O-ring serves as a gasketing means towards an abutting element—either the channel bushing 6 or the current injector plate 4. In FIG. 1, the furrow is not disclosed, and in order to secure the O-ring, a furrow may alternatively be provided in an abutting element: the channel bushing 16, or the current injector plate 4.

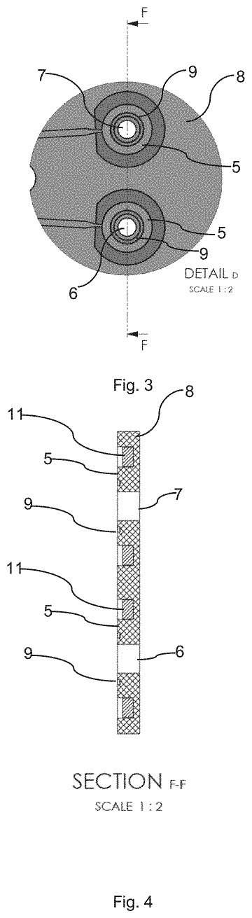

In FIGS. 2, 3 and 4, a sensor 11 is schematically shown inside the pocket 10. The sensor 11 is adapted to be responsive to the presence of magnetic fields or magnetic field changes which are going to be present at this location due to the channel 7,6 and the electric currents which are likely to pass along in the channel 7,6 whenever the electrolyser is powered up by the presence of a DC potential difference between the two current injector plates 4 in the presence of the electrolyte in the cells and in the channels 6,7.

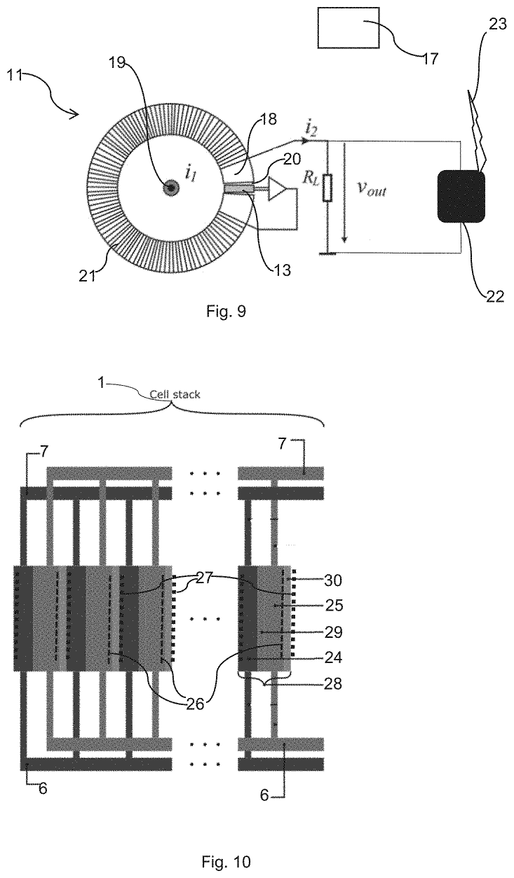

The sensor 11 may output an electrical signal, such as a current or an electrical potential. In FIG. 8 this is indicated by arrow Vₒᵤₜ. This signal may be digitized and transferred in any usual manner, such as by a wireless transmitter 22 (see FIG. 9) or through electric connection cables to a recording or displaying device 17 as disclosed in FIG. 8. Operators or digital surveillance and automated systems may now oversee the signal value or possible changes in the signal value, which either on its own or in combination with other information regarding the condition of the stack and the processes therein will give an indication of desirable or less desirable conditions. Operators or the digitized system may make changes to the operation conditions of the stack based on the recorded information from the sensor 11.

The pocket 10 may be arranged by milling away material around the rim 5, and possibly the pocket 10 has at least one opening 12 facing the surroundings. If the opening 12 is wide as shown in FIG. 1, the entire sensor 11 may be extracted therethrough also when the stack is assembled. As seen in FIG. 2, only a narrow opening 12 is provided in this embodiment. Here only a minor part of the sensor, such as a hall element 13 may be extracted therefrom in case a replacement is needed.

In an embodiment such as shown in FIGS. 2-4, a sensor 11 is provided at each of the anolyte and catholyte channels 6 as well as for the hydrogen and oxygen manifold channels 7. The oxygen and hydrogen exit manifold channels 7 carry a mixture of the electrolyte and the produced oxygen and hydrogen respectively. Due to the electrolyte part of such a mixture being conductive in nature, also in these channels an electric current may be present and measured. It is remarked, that in some kinds of electrolyser stacks, the anolyte and catholyte fluids are identical and may even be mixed in a tank prior to injection into the stacks, and it is only the end points of the respective manifolds: either cathode chambers or anode chambers, that determine whether a particular manifold channel is a catholyte or anolyte channel.

A sensor 11 is schematically shown in FIG. 8. Sensors of this kind are in themselves well known, and electric circuitry at the sensor may vary, giving rise to different electrical properties of the sensor. However, the sensors follow the same principle: the core 18 is provided around an electric lead 19, and in a radial slit opening 20 of the core 18, a hall element 13 is inserted. The core 18 is made from ferromagnetic material with a high magnetic permeability such that the magnetic field generated around the lead 19 due to the passage of electric current therein, shall be focused by the core 18 in the slit opening 20. The hall element 13 in the slit opening 20 is thus exposed to an enhanced magnetic field due to the current in the lead 19. In the sensor shown in FIG. 8, further an electric coil 21 is wound around the core. By this measure, the current in the electric coil 21 may be chosen to keep a predetermined output from the hall sensor, such as a zero output. The size of the needed current to this end will provide a measure of the electric current passing in the electric lead 19.

In case the insulation plate 8 is cut out from an endless lane of material, it is advantageous to mill out the pocket by conventional milling techniques. The insulation plate may be manufactured by other manufacturing techniques, such as by injection moulding and in this case, the pocket is simply made in the usual manner as a positive part of the one mould half.

The sensor 11 may be inserted in the pocket prior to the assembly of the stack, and a hardenable resin may be used to fill out any voids left in the pocket between the sensor and the insulation plate. In this case, naturally the sensor is not easily exchangeable, however it will sit well protected in the pocket 10 and be insulated from seeping electrolyte material, which in case the electrolyser is an alkaline and pressurized electrolyser is both chemically very aggressive, and pressurized. The material rim 5 indicated in FIG. 4 may in such cases be made with less regard to material strength, as the stresses added to the rim from the internal pressure in the channel, shall be carried, at least partially by the resin and the remaining insulator plate. Further, a reinforcement ring (not shown) may be provided externally of the material rim to increase its resilience against the internal pressure in the channel it surrounds. Such a ring may be made from material containing fibres such as carbon-carbon composites, aramid fibres, or may be made from metal compositions or combinations thereof.

In a further embodiment such as shown in FIG. 4, a void above or around the sensor remains, and possibly a soft polymer or foamed material (not shown) is added to the void or voids, prior to assembly of the stack to ensure that the sensor is maintained in a predefined position. This allows for the sensor to be removed from the stack, such as for the exchange thereof.

### 1. REFERENCE NUMBERS

1 Electrolyser cell stack
2 cell frames
3 end plate
4 current injector plate
5 material rim
6 Anolyte and catholyte input manifold channels
7 Oxygen and hydrogen exit manifold channels
8 Insulation plate
9 Insulator plate O-ring furrow
10 Pocket
11 Sensor
12 Opening
13 Hall element
14 Current injector plate O-ring furrow
15 O-ring
16 Channel bushing
17 Remote location recording or displaying device
18 Core
19 Electric lead
20 Radial slit opening
21 Electric coil
22 Transmission element
23 RF capability indicator
24 Anolyte chamber
25 Catholyte chamber
26 Cathode
27 Anode
28 Single cell
29 Diaphragm
30 Bipolar plate

What is claimed is:

1. Method of electric current measurement at an electrolyser cell stack comprising the following steps: provide at least one sensor having an element which is responsive to the presence of a magnetic flux and/or magnetic flux changes adjacent to an input or exit manifold channel outside of a current injector plate in the electrolyser stack, ensure an electric or a wireless connection between the sensor and a recording and/or display device, supply an electrical potential difference between two current injector plates having the electrolyser cell stack arranged between them, capture a signal value indicative of magnetic flux and/or magnetic flux change at the sensor location by the at least one sensor, make the at least one signal value available for storage and/or transmission to a remote location through the wired and/or wireless connection.

2. Method as claimed in claim 1, wherein an insulation plate is generated with a pocket, and arranged adjacent to a backside of a current injector plate, whereby the pocket is arranged to surround at least one of an anolyte or catholyte input manifold channel, an oxygen or hydrogen exit manifold channel in a predetermined distance therefrom leaving a material rim around the respective channel, and whereby the at least one sensor is inserted into the pocket.

3. Method as claimed in claim 1, whereby signals indicative of electric currents or electric current changes in all of an anolyte input manifold channel and a catholyte input manifold channel and an oxygen exit manifold channel and hydrogen exit manifold channel of a cell stack are captured and made available for storage and/or transmission.

4. Method as claimed in claim 2, whereby an O-ring or similar gasketing device is pressured towards the material rim around each of the manifold channels whereby the O-ring is adapted to reside in a u-shaped furrow in the current injector plate or adapted to reside in a u-shaped furrow in an endplate and/or to reside in a u-shaped furrow in the insulation plate.

5. Method as claimed in claim 4, whereby a sensor is arranged in the pocket, said sensor having a core with high magnetic permeability and is thereby subject to the magnetic field generated by the electric current in the respective manifold channel and in that at least one of a hall element and an electric coil is provided adjacent to the core, and whereby an electric response signal originating from the hall element and/or the electric coil is made available for storage and/or transmission to a remote location.

6. Method as claimed in claim 2, whereby the pocket is provided with a depth in the thickness direction of the insulator plate of no more than ⅘ of the insulator plate thickness.

7. Method as claimed in claim 6, whereby the pocket is milled out in the insulator plate prior to the insertion of the sensor.

8. Method as claimed in claim 2, whereby, in a step prior to assembly of the electrolyser cell stack, voids around the sensor are filled out with a hardenable resin, such that the insulator plate material around the pocket and the sensor and transmission element are embedded in the resin.

9. Method as claimed in claim 2, the sensor is inserted into the pocket prior to, during, or after the assembly of the electrolyser cell stack.

10. Electrolyser comprising a stack of cells and embedded in the stack, catholyte and anolyte input manifold channels adapted to feed catholyte and anolyte to respective catholyte and anolyte cell chambers, wherein catholyte chambers further comprise a cathode adapted to release hydrogen, and anolyte chambers comprise an anode adapted to release oxygen, when an electrolyte comprising alkaline water is supplied through the respective manifold channels and wherein gas and electrolyte manifold channels are provided and adapted for the capture of produced gasses, whereby a pocket is provided around at least one of an electrolyte manifold channel and a gas and electrolyte manifold channel and placed at a predetermined distance therefrom in an insulator plate arranged between an end plate and a current injector plate at one end of the stack, whereby the pocket is adapted to accommodate a sensor.

11. Electrolyser as claimed in claim 10, wherein at least one magnetic flux and/or magnetic flux change responsive touchless sensor is arranged in the pocket whereby the sensor is adapted to register values indicative of electric current densities and/or electric current density changes in a respective manifold channel and whereby additionally a transmission element for wireless or wired transmission of registered values is provided in the pocket along with the sensor.

12. Electrolyser as claimed in claim 10, wherein the pocket surrounds a manifold channel and is at least partially open to the surroundings.

13. Electrolyser as claimed in claim 11, wherein the sensor comprises a hall element and at least one of the two: a material with a high magnetic permeability such as a core, a coil.

14. Electrolyser as claimed in claim 10, the predefined distance is sufficient for the pressure in the channel to be contained.

15. Electrolyser as claimed in claim 10, wherein the sensor circumscribes the respective channel, and that the pocket is filled out by the sensor and/or hardenable resin provided between the sensor parts and pocket walls.
